(19) United States
(12) Patent Application Publication
(10) Pub. No.: US 2025/0329520 A1
(43) Pub. Date: Oct. 23, 2025

(54) DELIVERY OF CONFIGURABLE PULSED VOLTAGE WAVEFORMS FOR SUBSTRATE PROCESSING

(71) Applicant: Applied Materials, Inc., Santa Clara, CA (US)

(72) Inventors: Shouyin ZHANG, Santa Clara, CA (US); Sireesh ADIMADHYAM, Santa Clara, CA (US); Keith A. MILLER, Mountain View, CA (US)

(21) Appl. No.: 19/096,353

(22) Filed: Mar. 31, 2025

Related U.S. Application Data
(60) Provisional application No. 63/637,331, filed on Apr. 22, 2024.

(51) Int. Cl. H01J 37/34; C23C 14/34; C23C 14/54; H01L 21/285

(52) U.S. Cl. CPC H01J 37/3467; C23C 14/3485; C23C 14/54; H01J 37/3447; H01J 2237/332; H01L 21/2855

(57) ABSTRACT

Methods and apparatus for delivering configurable pulsed voltage waveforms to an electrode for substrate processing. One example method generally includes applying a positive DC bias relative to ground to a first electrode disposed within a processing region of a processing chamber. The positive DC bias is configured to alter a plasma potential relative to ground of a plasma formed in the processing region of the processing chamber. The method also generally includes delivering a pulsed-voltage (PV) waveform to a second electrode disposed in a substrate support within the processing chamber. Amplitudes of pulses of the PV waveform extend from a positive voltage relative to ground to a negative voltage relative to ground. The positive voltage relative to ground is greater than the plasma potential relative to ground.

### CROSS-REFERENCE TO RELATED APPLICATION

This application claims the benefit of and priority to U.S. Provisional Application 63/637,331 filed on Apr. 22, 2024, which is assigned to the assignee hereof and hereby expressly incorporated by reference herein in its entirety as if fully set forth below and for all applicable purposes.

### BACKGROUND

### Field

Embodiments of the present disclosure generally relate to substrate processing methods and apparatus. More specifically, embodiments of the present disclosure relate to delivering configurable pulsed voltage waveforms to an electrode for processing semiconductor substrates.

### Description of the Related Art

Physical vapor deposition (PVD) is one of many substrate processing techniques. PVD is a common technique used for depositing thin films of various metals and metal alloys on a substrate. Some PVD processes are enhanced by forming a plasma in a processing region of a processing chamber. By controlling properties of the plasma such as ion energy, the deposition process can also be controlled to improve uniformity and deposition quality. However, some aspects of a PVD process may cause a plasma potential of the plasma to become highly biased relative to ground. While the plasma potential is highly biased, conventional substrate biasing techniques, which are ground referenced and used to control the plasma interaction with the substrate during processing, are not able to control the ion energies in a low ion energy range due to the large difference between the plasma potential and ground. The low ion energies are often necessary to prevent damage to some of the fragile materials (e.g., low-k materials) and fragile device structures formed on exposed regions of the substrate.

Accordingly, there is a need in the art for a method and apparatus that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the present disclosure are directed to a method. The method generally includes applying a positive DC bias relative to ground to a first electrode disposed within a processing region of a processing chamber. The positive DC bias is configured to alter a plasma potential relative to ground of a plasma formed in the processing region of the processing chamber. The method also generally includes delivering a pulsed-voltage (PV) waveform to a second electrode disposed in a substrate support within the processing chamber. Amplitudes of pulses of the PV waveform extend from a positive voltage relative to ground to a negative voltage relative to ground. The positive voltage relative to ground is greater than the plasma potential relative to ground.

Embodiments of the present disclosure provide a physical vapor deposition (PVD) system. The PVD system generally includes a processing chamber, a DC voltage source, and a PV source. The DC voltage source is configured to apply a positive DC bias relative to ground to a first electrode disposed within a processing region of the processing chamber. The positive DC bias is configured to alter a plasma potential relative to ground of a plasma formed in the processing region. The PV source is configured to deliver a PV waveform to a second electrode disposed in the processing chamber. Amplitudes of pulses of the PV waveform extend from a positive voltage relative to ground to a negative voltage relative to ground. The positive voltage relative to ground is greater than plasma potential relative to ground.

Embodiments of the present disclosure provide one or more non-transitory computer readable media storing executable instructions that, when executed by at least one processor, cause the at least one processor to perform operations. The operations generally include applying a positive DC bias relative to ground to a first electrode disposed within a processing region of a processing chamber. The positive DC bias is configured to alter a plasma potential relative to ground of a plasma formed in the processing region of the processing chamber. The operations also generally include delivering a PV waveform to a second electrode disposed in a substrate support within the processing chamber. Amplitudes of pulses of the PV waveform extend from a first positive voltage relative to ground to a second positive voltage relative to ground. The first positive voltage relative to ground is less than the plasma potential relative to ground and the second positive voltage relative to ground is greater than the plasma potential relative to ground.

Embodiments of the present disclosure are directed to a method. The method generally includes (i) applying a positive DC bias relative to ground to a first electrode disposed within a processing region of a processing chamber, where the positive DC bias is configured to alter a plasma potential relative to ground of a plasma formed in the processing region of the processing chamber, and (ii) delivering a PV waveform to a second electrode disposed in a substrate support within the processing chamber, where amplitudes of pulses of the PV waveform extend from a positive voltage relative to ground to a negative voltage relative to ground, and where the positive voltage relative to ground is between the plasma potential and ground.

Embodiments of the present disclosure provide a physical vapor deposition (PVD) system. The PVD system generally includes (i) a processing chamber, (ii) a DC voltage source configured to apply a positive DC bias relative to ground to a first electrode disposed within a processing region of the processing chamber, where the positive DC bias is configured to alter a plasma potential relative to ground of a plasma formed in the processing region, and (iii) a PV source configured to deliver a PV waveform to a second electrode disposed in the processing chamber, where amplitudes of pulses of the PV waveform extend from a positive voltage relative to ground to a negative voltage relative to ground, and where the positive voltage relative to ground is between the plasma potential and ground.

Embodiments of the present disclosure provide one or more non-transitory computer readable media storing executable instructions that, when executed by at least one processor, cause the at least one processor to perform operations. The operations generally include (i) applying a positive DC bias relative to ground to a first electrode disposed within a processing region of a processing chamber, where the positive DC bias is configured to alter a plasma potential relative to ground of a plasma formed in the processing region of the processing chamber, and (ii) delivering a pulsed-voltage (PV) waveform to a second electrode disposed in a substrate support within the processing chamber, where amplitudes of pulses of the PV waveform extend from a first positive voltage relative to ground to a second positive voltage relative to ground, and where the first positive voltage relative to ground is between the plasma potential and ground.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a cross-sectional view of a processing chamber, in which embodiments of the present disclosure may be implemented.

FIG. 2 illustrates a graph of a pulsed-voltage (PV) waveform with pulses having a first example amplitude, according to one or more embodiments described herein.

FIG. 3 illustrates a graph of a PV waveform with pulses having a second example amplitude, according to one or more embodiments described herein.

FIG. 4 is a flow diagram illustrating a method for delivering a PV waveform to an electrode disposed in a substrate support, according to one or more embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to plasma processing techniques, such as metal deposition processes. More specifically, embodiments of the present disclosure relate to delivering configurable pulsed voltage waveforms to an electrode for substrate processing. In some embodiments, a positive DC bias relative to ground may be applied to a collimator (e.g., a flux optimizer) disposed within a processing region of a physical vapor deposition (PVD) processing chamber. The positive DC bias may be configured to alter a plasma potential relative to ground of a plasma formed in the processing region of the processing chamber. Altering the plasma potential relative to ground of the plasma may prevent (or at least reduce) the generation of ion energies in a range between ground and the plasma potential relative to ground. Ions having ion energies in this range may be used in various PVD processes, such as PVD processes that include the deposition of a material on a fragile material (e.g., low-k material) and/or fragile device structures formed on a substrate.

A pulsed-voltage (PV) waveform may be delivered to an electrode disposed in a substrate support within the processing chamber. Pulses of the PV waveform may have amplitudes that extend from a positive voltage relative to ground to a negative voltage relative to ground. In some embodiments, the positive voltage relative to ground is greater than the plasma potential relative to ground. Because of this, it is possible to generate the ion energies in a range between ground and the plasma potential relative to ground.

### Processing Chamber Examples

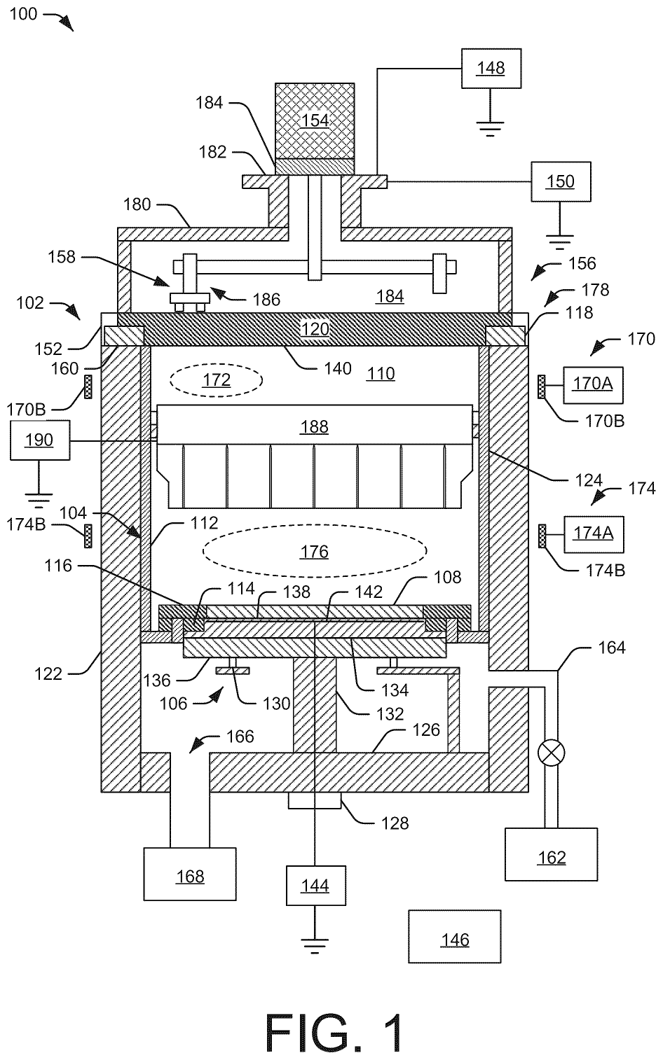

FIG. 1 illustrates a cross-sectional view of a processing chamber 100, in which embodiments of the present disclosure may be implemented. The processing chamber 100 includes an upper process assembly 102, a process kit 104, and a pedestal assembly 106, which are all configured to process a substrate 108 disposed in a processing region 110. The process kit 104 includes a one-piece grounded shield 112, a deposition ring 114, a cover ring 116, and an isolator ring assembly 118. In the version shown, the processing chamber 100 includes a sputtering chamber, also called a physical vapor deposition (PVD) chamber, capable of depositing a single or multi-compositional material from a sputtering target 120 on the substrate 108. The processing chamber 100 may also be used to deposit aluminum (AI), copper (Cu), nickel (Ni), platinum (Pt), hafnium (Hf), silver (Ag), chrome (Cr), gold (Au), molybdenum (Mo), silicon (Si), ruthenium (Ru), tantalum (Ta), tantalum nitride (TaN), tantalum carbide (TaC), titanium nitride (TiN), tungsten (W), tungsten nitride (WN), lanthanum (La), alumina (AlOₓ), lanthanum oxides (LaOₓ), nickel platinum alloys (NiPt), and titanium (Ti), and or a combination thereof.

The processing chamber 100 includes a chamber body 122 having sidewalls 124, a bottom wall 126, and the upper process assembly 102 that enclose the processing region 110 or plasma zone. The chamber body 122 is typically fabricated from welded plates of stainless steel or a unitary block of aluminum. In some embodiments, the sidewalls include aluminum and the bottom portion of the chamber includes one or more walls that are formed from a stainless steel plate. The sidewalls 124 generally contain a slit valve (not shown) to provide for entry and egress of the substrate 108 from the processing chamber 100. Components in the upper process assembly 102 of the processing chamber 100 in cooperation with the grounded shield 112, pedestal assembly 106, and cover ring 116 confine the plasma formed in the processing region 110 to the region above the substrate 108.

The pedestal assembly 106 is supported from the bottom wall 126 of the processing chamber 100. The pedestal assembly 106 supports the deposition ring 114 along with the substrate 108 during processing. The pedestal assembly 106 is coupled to the bottom wall 126 of the processing chamber 100 by a lift mechanism 128, which is configured to move the pedestal assembly 106 between an upper processing position and lower transfer position. Additionally, in the lower transfer position, lift pins 130 are moved through the pedestal assembly 106 to position the substrate 108 a distance from the pedestal assembly 106 to facilitate the exchange of the substrate with a substrate transfer mechanism disposed exterior to the processing chamber 100, such as a single blade robot (not shown). A bellows 132 is typically disposed between the pedestal assembly 106 and the bottom wall 126 to isolate the processing region 110 from the interior of the pedestal assembly 106 and the exterior of the chamber.

The pedestal assembly 106 generally includes a substrate support 134 sealingly coupled to a platform housing 136. The platform housing 136 is typically fabricated from a metallic material such as stainless steel or aluminum. A cooling plate (not shown) is generally disposed within the platform housing 136 enabling thermal regulation of the substrate support 134.

The substrate support 134 may be comprised of aluminum or ceramic. The substrate support 134 has a substrate receiving surface 138 that receives and supports the substrate 108 during processing, the substrate receiving surface 138 being substantially parallel to a sputtering surface 140 of the sputtering target 120. The substrate support 134 may be an electrostatic chuck, a ceramic body, a heater, or a combination thereof. In some embodiments, the substrate support 134 is an electrostatic chuck that includes a dielectric body having an electrode 142, embedded therein. The dielectric body is typically fabricated from a high thermal conductivity dielectric material such as pyrolytic boron nitride, aluminum nitride, silicon nitride, alumina or an equivalent material. Other aspects of the pedestal assembly 106 and substrate support 134 are further described below. In some embodiments, the electrode 142 is configured so that when a DC voltage is applied to the electrode 142, a substrate 108 disposed on the substrate receiving surface 138 will be electrostatically chucked thereto to improve the heat transfer between the substrate 108 and the substrate support 134. In some embodiments, a pulsed-voltage (PV) waveform source 144 is electrically coupled to the electrode 142, and is configured to generate a pulsed-voltage signal that includes a PV waveform so that a pulsed voltage signal can be provided to the substrate 108 during processing to affect and control the plasma interaction with the surface of the substrate 108.

A program (or computer instructions) readable by a system controller 146 determines which tasks are performable on a substrate. In some embodiments, the system controller 146 includes a computing device having one or more processors, memory, and storage. The one or more processors can include central processing units, graphics processing units, accelerators, etc. The memory includes main memory for storing instructions for the one or more processors to execute or data for the one or more processors to operate on. For example, the memory includes random access memory (RAM). The storage includes mass storage for data or instructions. As an example and not by way of limitation, the storage may include a removable disk drive, flash memory, an optical disc, a magneto-optical disc, magnetic tape, or a Universal Serial Bus drive or two or more of these. The storage may include removable or fixed media and may be internal or external to the computing device. The storage may include any suitable form of non-volatile, solid-state memory, or read-only memory. The system controller 146 includes a non-transitory computer readable medium or media. The non-transitory computer readable medium or media may include one or more semiconductor-based or other integrated circuits (ICs) (such, as for example, field-programmable gate arrays or application-specific ICs), hard disk drives, hybrid hard drives, optical discs, optical disc drives, magneto-optical discs, magneto-optical drives, solid-state drives, RAM drives, any other suitable non-transitory computer readable storage medium/media, or any suitable combination. The non-transitory computer readable medium or media may be volatile, non-volatile, or a combination of volatile and non-volatile.

Preferably, the program is software readable by the system controller 146 that includes code to perform tasks relating to monitoring, execution, and control of the movement and various process recipe tasks and recipe steps being performed in the processing chamber 100. For example, the program can include program code that includes a substrate positioning instruction set to operate the pedestal assembly 106; a gas flow control instruction set to operate gas flow control valves to set a flow of sputtering gas to the processing chamber 100; a gas pressure control instruction set to operate a throttle valve or gate valve to maintain a pressure in the processing chamber 100; a temperature control instruction set to control a temperature control system (not shown) in the pedestal assembly 106 or sidewalls 124 to set temperatures of the substrate 108 or sidewalls 124, respectively; and a process monitoring instruction set to monitor the process in the processing chamber 100.

The upper process assembly 102 may also include an RF source 148, a direct current (DC) source 150, an adaptor 152, a motor 154, and a lid assembly 156. The lid assembly 156 generally includes the sputtering target 120, and a magnetron system 158 that includes a magnetron 186. The upper process assembly 102 is supported by the sidewalls 124 when in a closed position, as shown in FIG. 1. A ceramic target isolator 160 is disposed between the isolator ring assembly 118, the sputtering target 120, and the adaptor 152 of the lid assembly 156 to prevent vacuum leakage there between. The adaptor 152 is sealably coupled to the sidewalls 124, and is configured to help with the removal of the upper process assembly 102 and isolator ring assembly 118.

When in the processing position, the sputtering target 120 is disposed adjacent to the adaptor 152, and is exposed to the processing region 110 of the processing chamber 100. The sputtering target 120 contains material that is deposited on the substrate 108 during a PVD, or sputtering, process. The isolator ring assembly 118 is disposed between the sputtering target 120 and the shield 112. The chamber body 122 may electrically isolate the sputtering target 120 from the shield 112.

During processing, the sputtering target 120 is biased relative to a grounded region of the processing chamber 100 (e.g., the chamber body 122 and the adaptor 152) by a power source disposed in the RF source 148 and/or the DC source 150. It is believed that by delivering RF energy and/or DC power to the sputtering target 120 during a high pressure PVD process, significant process advantages can be achieved over conventional low pressure DC plasma processing techniques when used in conjunction with sputtering materials such as titanium, copper, nickel, ruthenium, aluminum, tantalum, molybdenum, tungsten, and other materials. In some embodiments, the RF source 148 includes an RF power source and an RF match (not shown) that are configured to efficiently deliver RF energy to the sputtering target 120. In some examples, the RF power source is capable of generating RF currents at a frequency of between about 13.56 MHz and about 228 MHz at powers between about 0.1 and about 5 KW. In one or more examples, a DC power supply included in the DC source 150 is capable of delivering between about 0.1 and about 50 KW of DC power.

During processing, a gas, such as argon, is supplied to the processing region 110 from a gas source 162 via conduits 164. The gas source 162 may include an inert gas such as argon, krypton, helium or xenon, which is capable of energetically impinging upon and sputtering material from the sputtering target 120 and/or surface of the substrate 108 based on a bias applied which may be applied by the PV waveform source 144. The gas source 162 may also include a reactive gas, such as one or more of an oxygen-containing gas or a nitrogen-containing gas, which is capable of reacting with the sputtering material to form a layer on a substrate. Spent process gas and byproducts are exhausted from the processing chamber 100 through exhaust ports 166 that receive spent process gas and direct the spent process gas to an exhaust conduit having an adjustable position gate valve (not shown) to control the pressure in the processing region 110 in the processing chamber 100. The exhaust conduit is connected to one or more exhaust pumps 168, such as a cryopump. Typically, the pressure of the sputtering gas in the processing chamber 100 during processing is set to sub-atmospheric levels, such as a vacuum environment, for example, a pressure of about 0.6 mTorr to about 300 mTorr. In some embodiments, the processing pressure is set to about 20 mTorr to about 100 mTorr.

In some embodiments, a first electromagnet assembly 170 includes a first current source 170A configured to bias a first magnetic coil assembly 170B. The first magnetic coil assembly 170B is positioned near the sputtering target 120, configured to modulate a magnetron-controlled plasma 172. A second electromagnet assembly 174 includes a second current source 174A configured to bias a second magnetic coil assembly 174B. The second magnetic coil assembly 174B is positioned in the central part of the chamber, and configured to modulate a central portion of a plasma 176. The plasma 176 is formed between the substrate 108 and the sputtering target 120 from the gas. Ions within the plasma 176 are accelerated toward the sputtering target 120 and cause material to become dislodged from the sputtering target 120. The dislodged target material is deposited on the substrate 108.

A lid enclosure 178 generally includes a conductive wall 180, a center feed 182, and shielding (not shown). In this configuration, the conductive wall 180, the center feed 182, the sputtering target 120, and a portion of the motor 154 enclose and form a back region 184. The back region 184 is a sealed region disposed on the backside of the sputtering target 120 and is generally filled with a flowing liquid during processing to remove the heat generated at the sputtering target 120 during processing. In some embodiments, the conductive wall 180 and the center feed 182 are configured to support the motor 154 and magnetron system 158, so that the motor 154 can rotate the magnetron system 158 during processing. In one or more embodiments, the motor 154 is electrically isolated from the RF or DC power delivered from the power supplies by use of a dielectric layer, such as Delrin, G10, or Ardel. The shielding (not shown) may include one or more dielectric materials that are positioned to enclose and prevent the RF energy delivered to the sputtering target 120 from interfering with and affecting other processing chambers. In some embodiments, the shielding may include a Delrin, G10, Ardel or other similar material and/or a thin-grounded sheet metal RF shield.

To provide efficient sputtering, a magnetron system 158 is positioned behind the sputtering target 120 in the upper process assembly 102 to create a magnetic field in the processing region 110 adjacent the sputtering surface 140 of the sputtering target 120, which generates the magnetron-controlled plasma 172. A magnetic field generated by the magnetron system 158 traps electrons and ions to increase the plasma density over one or more regions of the sputtering target 120, and to increase target utilization, control deposition uniformity, and the sputtering rate. In some embodiments, the magnetron system 158 includes a source magnetron assembly (not shown) that includes an outer pole (not shown) and an inner pole (not shown). The magnetron system 158 is rotated about a central axis of the processing chamber 100 by use of the motor 154. In some embodiments, a “closed loop” magnetron configuration is formed within the magnetron system 158 such that the outer pole (not shown) of the magnetron surrounds the inner pole (not shown) of the magnetron forming a gap between the poles that is a continuous loop. In the closed loop configuration, the magnetic fields that emerge and reenter through a surface of the sputtering target form a “closed loop” pattern can be used to confine electrons near the surface of the sputtering target in a closed pattern, which is often called a “racetrack” type pattern. A closed loop, as opposed to the open loop, magnetron configuration is able to confine electrons and generate a high density plasma near the sputtering surface 140 of the sputtering target 120 to increase the sputtering yield. In some other embodiments, an “open loop” magnetron configuration is formed within the magnetron system 158 such that the outer pole of the magnetron surrounds the inner pole of the magnetron forming a gap between the poles that is a continuous loop. In an open loop magnetron configuration, the electrons trapped between the inner and outer poles will migrate, leak out, and escape from the B-fields created at open ends of the magnetron, thus only holding the electrons for a short period of time during the sputtering process due to the reduced confinement of the electrons. It has been found that the use of an open loop magnetron configuration can provide significant step coverage improvements and provide an improved material composition uniformity across the substrate surface, when used in conjunction with the RF and DC sputtering of multi-compositional targets described herein.

In some embodiments, the processing chamber 100 includes a collimator 188 (e.g., a flux optimizer) having a plurality of apertures configured to direct material from the sputtering target 120 though the collimator 188 and towards the substrate 108 in a manner that can control/adjust a number of ions arriving and an angle of arrival of the ions onto portions of the substrate 108. In one or more embodiments, a DC voltage source 190 is electrically coupled to the collimator 188 and configured to apply a positive DC bias to the collimator 188 relative to ground. The positive DC bias is configured to attract sputtered metal ions formed in the magnetron-controlled plasma 172. In some examples, the positive DC bias is configured to alter a plasma potential relative to ground of the plasma 176 formed in the processing region 110 of the processing chamber 100. In some embodiments, the positive DC bias is a voltage in a range of 0.1 V to 300 V. In other embodiments, the positive DC bias may be greater than 300 V.

In various embodiments, altering the plasma potential relative to ground may cause the plasma potential of the plasma 176 to be up to 200 V greater than the positive DC bias applied to the collimator 188 relative to ground. If the PV waveform source 144 delivers the PV waveform to the electrode 142 having pulses with amplitudes that extend from ground or a first negative voltage relative to ground to a second negative voltage relative to ground, then it is not possible to cause ions to have energy levels below a threshold energy level. For example, it is not possible to generate ion energies in a range from ground to the plasma potential of the plasma 176. However, ions having ion energies in the range from ground to the plasma potential are necessary for various low energy, directional deposition processes and/or processes involving materials with a relatively low relative permittivity.

In order to generate ion energies in the range from ground to the plasma potential of the plasma 176, the one or more processors of the system controller 146 execute instructions that cause the one or more processors to reconfigure the amplitudes of the pulses in the PV waveform. In some examples, the one or more processors adjust the amplitudes to extend from a positive voltage relative ground to a negative voltage relative to ground. The positive voltage relative to ground may be greater than the plasma potential relative to ground. In other examples, the one or more processors adjust the amplitudes to extend from a first positive voltage relative to ground to a second positive voltage relative to ground. The first positive voltage relative to ground may be greater than the plasma potential relative to ground. The second positive voltage relative to ground may be less than the plasma potential relative to ground.

### Pulsed-Voltage Waveform Examples

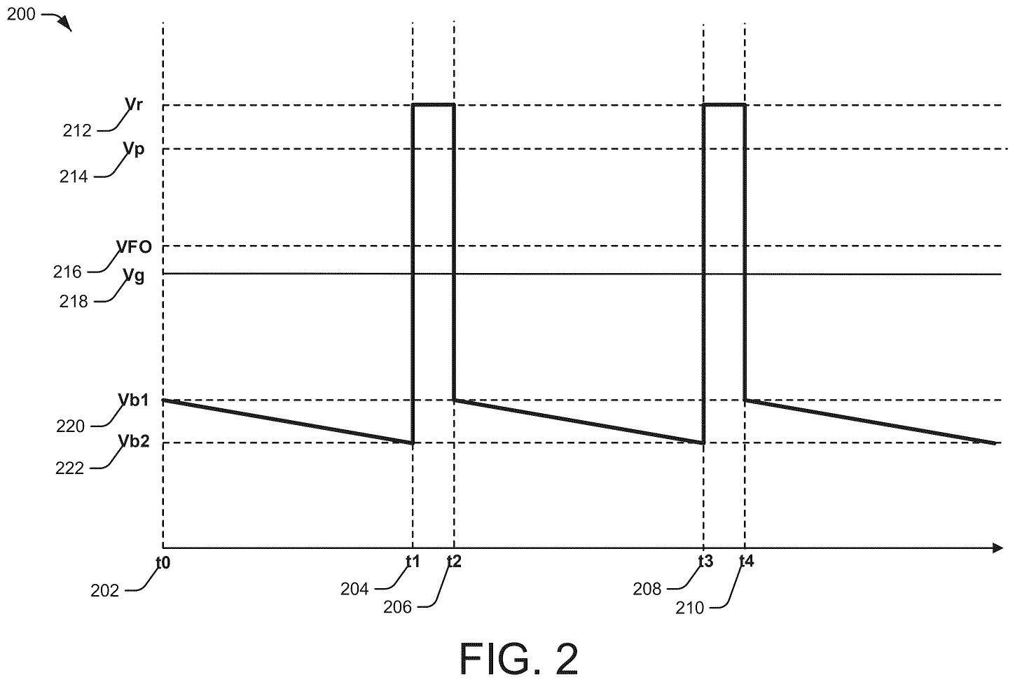

FIG. 2 illustrates a graph 200 of a pulsed-voltage (PV) waveform with pulses having a first example amplitude, according to one or more embodiments described herein. As shown in FIG. 2, an x-axis of the graph 200 includes time t0 202, time t1 204, time t2 206, time t3 208, and time t4 210. A y-axis of the graph 200 includes Vr 212, Vp 214, VFO 216, Vg 218, Vb1 220, and Vb2 222. In some embodiments, Vr 212 represents a controllable/configurable reversal voltage; Vp 214 represents the plasma potential of the plasma 176; VFO 216 represents the positive DC bias applied to the collimator 188 by the DC voltage source 190; Vg 218 represents ground potential of the processing chamber 100 (e.g., 0 V); Vb1 220 represents a voltage applied to the electrode 142 by the PV waveform source 144 at the start of pulse on-time (e.g., a biasing time); and Vb2 222 represents a voltage applied to the electrode 142 by the PV waveform source 144 at the end of the pulse on-time (e.g., the biasing time). In one or more embodiments, a value of Vb1 220 is determined based on need of ion energy and coupling conditions of a power delivery system such as the PV waveform source 144. In some examples, a value of Vb2 222 is determined based on the value of Vb1 220 and plasma conditions to maintain as flat/stable as possible the DC voltage for the plasma sheath.

At time t0 202, a first pulse of the PV waveform delivered to the electrode 142 by the PV waveform source 144 has started a pulse on-time at which time a voltage is applied to the electrode 142 is equal to Vb1 220. At time t1 204, the pulse on-time for the first pulse ends at which time the voltage applied to the electrode 142 is modified from Vb2 222 to Vr 212 to start a pulse off-time. At time t2 206, the pulse off-time ends and a second pulse of the PV waveform starts a pulse on-time. As shown, the voltage applied to the electrode 142 is modified from Vr 212 to Vb1 220. Accordingly, an amplitude of the second pulse extends from Vr 212 relative to ground Vg 218 to Vb1 220 relative to ground Vg 218. In the graph 200, Vr 212 is a positive voltage relative to ground Vg 218 and Vb1 220 is a negative voltage relative to ground Vg 218.

At time t3 208, the pulse on-time for the second pulse ends, and the voltage applied to the electrode 142 is modified from Vb2 222 to Vr 212 to start a pulse off-time. At time t4 210, the pulse off-time ends and a third pulse of the PV waveform starts a pulse on-time. An amplitude of the third pulse extends from Vr 212 (which is a positive voltage relative to ground Vg 218) to Vb1 220 (which is a negative voltage relative to ground Vg 218). By changing Vr 212 from a negative voltage relative to ground Vg 218 to the positive voltage relative to ground Vg 218, it is possible to cause ions to have ion energies in the range from ground Vg 218 to the plasma potential Vp 214 of the plasma 176.

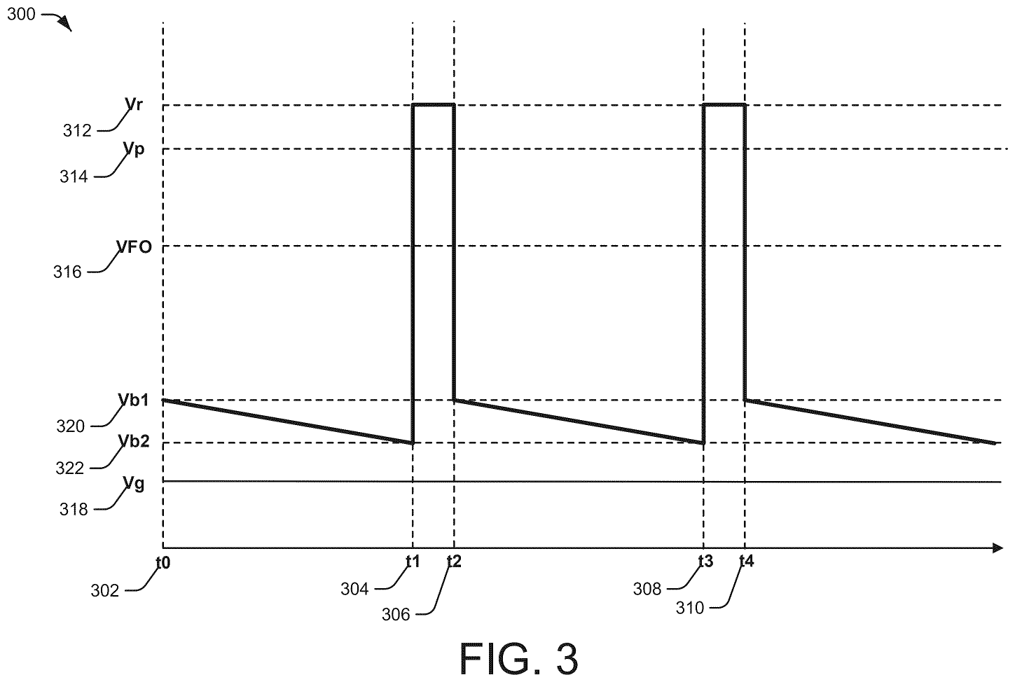

FIG. 3 illustrates a graph 300 of a pulsed-voltage (PV) waveform with pulses having a second example amplitude, according to one or more embodiments described herein. Similar to the graph 200, an x-axis of the graph 300 includes time t0 302, time t1 304, time t2 306, time t3 308, and time t4 310. A y-axis of the graph 300 includes Vr 312, Vp 314, VFO 316, Vg 318, Vb1 320, and Vb2 322. Like the example described with respect to FIG. 2, Vr 312 represents a controllable/configurable reversal voltage; Vp 314 represents the plasma potential of the plasma 176; VFO 316 represents the positive DC bias applied to the collimator 188 by the DC voltage source 190; Vg 318 represents ground potential of the processing chamber 100 (e.g., 0 V); Vb1 320 represents a voltage applied to the electrode 142 by the PV waveform source 144 at the start of a pulse on-time (e.g., a biasing time); and Vb2 322 represents a voltage applied to the electrode 142 by the PV waveform source 144 at the end of the pulse on-time (e.g., the biasing time).

At time t0 302, a first pulse of the PV waveform delivered to the electrode 142 by the PV waveform source 144 has started a pulse on-time and a voltage applied to the electrode 142 is equal to Vb1 320. At time t1 304, the pulse on-time for the first pulse ends, and the voltage applied to the electrode 142 is modified from Vb2 322 to Vr 312 to start a pulse off-time. Like the example in the graph 200, Vr 312 is a positive voltage relative to ground Vg 318. At time t2 306, the pulse off-time ends and a second pulse of the PV waveform starts a pulse on-time. As shown, at time t2 306, the voltage applied to the electrode 142 is modified from Vr 312 to Vb1 320. Accordingly, an amplitude of the second pulse extends from Vr 312 relative to ground Vg 318 to Vb1 320 relative to ground Vg 318. In the graph 300, Vr 312 is a first positive voltage relative to ground Vg 318 and Vb1 320 is a second positive voltage relative to ground Vg 318. In the illustrated example, Vr 312 is greater than Vp 314 relative to ground Vg 318 and Vb1 320 is less than Vp 314 relative to ground Vg 318.

At time t3 308, the pulse on-time for the second pulse ends, and the voltage applied to the electrode 142 is modified from Vb2 322 to Vr 312 to start a pulse off-time. At time t4 310, the pulse off-time ends and a third pulse of the PV waveform starts a pulse on-time. An amplitude of the third pulse extends from Vr 312 (which is the first positive voltage relative to ground Vg 318) to Vb1 320 (which is the second positive voltage relative to ground Vg 318). By changing Vr 312 from a first negative voltage relative to ground Vg 318 to the first positive voltage relative to ground Vg 318 and by changing Vb1 320 from a second negative voltage relative to ground Vg 318 to the second positive voltage relative to ground Vg 318, it is possible to cause ions to have ion energies in the range from ground Vg 318 to the plasma potential Vp 314 of the plasma 176 even though the plasma potential Vp 314 is relatively highly biased.

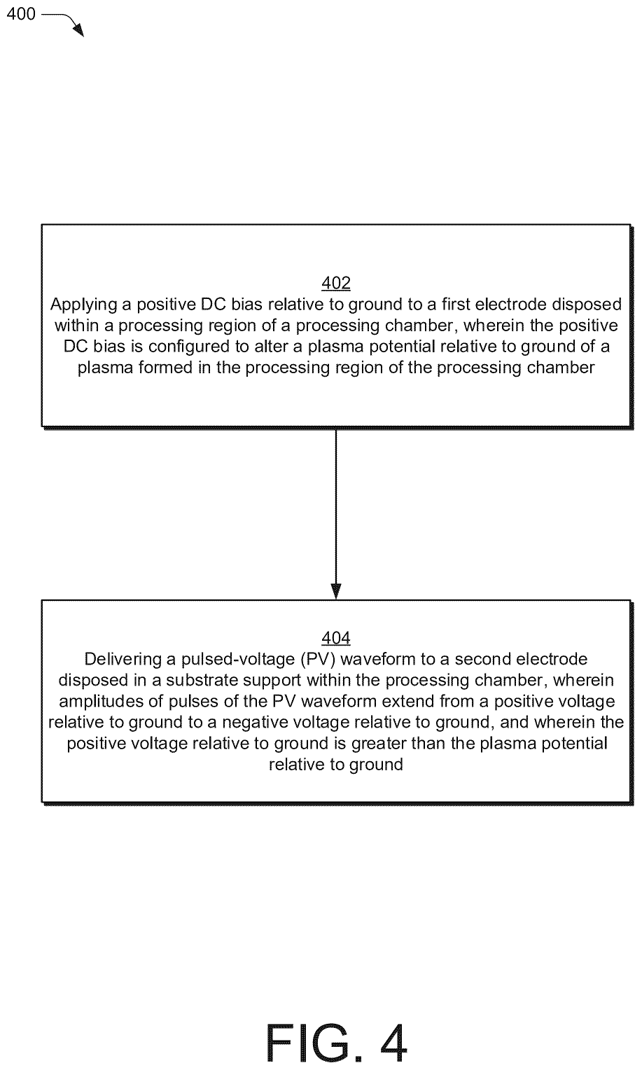

FIG. 4 is a flow diagram illustrating a method 400 for delivering a pulsed-voltage (PV) waveform to an electrode disposed in a substrate support, according to one or more embodiments described herein. At operation 402, a positive DC bias relative to ground is applied to a first electrode disposed within a processing region of a processing chamber, wherein the positive DC bias is configured to alter a plasma potential relative to ground of a plasma formed in the processing region of the processing chamber. In some embodiments, the positive DC bias is applied relative to ground to the collimator 188 by the DC voltage source 190, and the positive DC bias is configured to alter the plasma potentials Vp 214, Vp 314 relative to ground Vg 218, Vg 318, respectively, of the plasma 176. At operation 404, in some embodiments, a PV waveform is delivered to a second electrode disposed in a substrate support within the processing chamber, amplitudes of pulses of the PV waveform extend from a positive voltage relative to ground to a negative voltage relative to ground, the positive voltage relative to ground is greater than the plasma potential relative to ground. Alternately, at operation 404, in some embodiments, a PV waveform is delivered to a second electrode disposed in a substrate support within the processing chamber, amplitudes of pulses of the PV waveform extend from a positive voltage relative to ground to a negative voltage relative to ground, the positive voltage relative to ground is disposed between the plasma potential and ground. In one or more embodiments, the PV waveform is delivered to the electrode 142 by the PV waveform source 144 and the amplitudes of the pulses extend from Vr 212 relative to ground Vg 218 to Vb1 220 relative to ground Vg 218.

### Additional Considerations

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

As used herein, “a CPU”, “controller”, “a processor”, “at least one processor”, or “one or more processors”, generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “a memory”, “at least one memory”, or “one or more memories”, generally refers to a single memory configured to store data and/or instructions, multiple memories configured to collectively store data and/or instructions.

As used herein, “gas” and “fluid” may be used interchangeable with either term generally referring to elements, compounds, materials, etc., having the properties of a gas, a fluid, or both a gas and a fluid.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some” refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

“Coupled” and “coupling” means that the subsequently described material is connected to previously described material. The connection may be a direct, or indirect connection, and may, or may not, include intermediary components such as plumbing, wiring, fasteners, mechanical power transmission, electrical communication, wired and/or wireless transmission, etc., which may suitable to affect operation of the components.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining” may include resolving, selecting, choosing, and establishing.

When the word “approximately” or “about” are used, this term may mean that there may be a variance in value of up to +10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112 (f), for any limitations of any of the claims, except for those in which the claim expressly uses the words ‘means for’ together with an associated function.

The following claims are not intended to be limited to the embodiments provided but rather are to be accorded the full scope consistent with the language of the claims.

What is claimed is:

1. A method comprising:
applying a positive DC bias relative to ground to a first electrode disposed within a processing region of a processing chamber, wherein the positive DC bias is configured to alter a plasma potential relative to ground of a plasma formed in the processing region of the processing chamber; and
delivering a pulsed-voltage (PV) waveform to a second electrode disposed in a substrate support within the processing chamber, wherein amplitudes of pulses of the PV waveform extend from a positive voltage relative to ground to a negative voltage relative to ground, and wherein the positive voltage relative to ground is greater than the plasma potential relative to ground.

2. The method of claim 1, wherein the amplitudes of the pulses extend from positive 500 V relative to ground to negative 10 kV relative to ground.

3. The method of claim 1, wherein the positive voltage relative to ground is greater than 300 V relative to ground.

4. The method of claim 1, wherein the processing chamber is a physical vapor deposition (PVD) processing chamber.

5. The method of claim 1, further comprising depositing at least one of a metal or a metal alloy on a substrate within the processing chamber.

6. The method of claim 1, wherein the first electrode includes a collimator having a plurality of apertures.

7. The method of claim 6, wherein the first electrode is disposed between a sputtering target and the substrate support.

8. The method of claim 1, wherein the positive voltage relative to ground is up to 200 V relative to ground greater than the plasma potential relative to ground.

9. A physical vapor deposition (PVD) system, comprising:
a processing chamber;
a DC voltage source configured to apply a positive DC bias relative to ground to a first electrode disposed within a processing region of the processing chamber, wherein the positive DC bias is configured to alter a plasma potential relative to ground of a plasma formed in the processing region; and
a pulsed-voltage (PV) source configured to deliver a PV waveform to a second electrode disposed in the processing chamber, wherein amplitudes of pulses of the PV waveform extend from a positive voltage relative to ground to a negative voltage relative to ground, and wherein the positive voltage relative to ground is greater than plasma potential relative to ground.

10. The PVD system of claim 9, wherein the second electrode is disposed in a substrate support in the processing chamber.

11. The PVD system of claim 9, wherein the amplitudes of the pulses extend from positive 300 V relative to ground to negative 10 kV relative to ground.

12. The PVD system of claim 9, wherein the positive voltage relative to ground is greater than 300 V relative to ground.

13. The PVD system of claim 9, wherein the first electrode includes a collimator having a plurality of apertures.

14. The PVD system of claim 13, wherein the first electrode is disposed between a sputtering target and the second electrode.

15. One or more non-transitory computer readable media storing executable instructions that, when executed by at least one processor, cause the at least one processor to perform operations comprising:
applying a positive DC bias relative to ground to a first electrode disposed within a processing region of a processing chamber, wherein the positive DC bias is configured to alter a plasma potential relative to ground of a plasma formed in the processing region of the processing chamber; and
delivering a pulsed-voltage (PV) waveform to a second electrode disposed in a substrate support within the processing chamber, wherein amplitudes of pulses of the PV waveform extend from a first positive voltage relative to ground to a second positive voltage relative to ground, and wherein the first positive voltage relative to ground is greater than the plasma potential relative to ground and the second positive voltage relative to ground is less than the plasma potential relative to ground.

16. The one or more non-transitory computer readable media of claim 15, wherein the first electrode includes a collimator having a plurality of apertures.

17. The one or more non-transitory computer readable media of claim 15, wherein the second positive voltage relative to ground is up to 200 V relative to ground greater than the plasma potential relative to ground.

18. The one or more non-transitory computer readable media of claim 15, wherein the first electrode is disposed between a sputtering target and the second electrode.

19. The one or more non-transitory computer readable media of claim 15, wherein the processing chamber is a physical vapor deposition (PVD) processing chamber.

20. The one or more non-transitory computer readable media of claim 15, wherein the positive DC bias relative to ground is less than 300 V relative to ground.
